(19) United States
(12) Patent Application Publication
(10) Pub. No.: US 2010/0149739 A1
(43) Pub. Date: Jun. 17, 2010

(54) PROTECTIVE COVER FOR AN eREADER

(76) Inventors: Patrick Mish, Odenton, MD (US); Jim Ward, Ashburn, VA (US); Adam Ashley, Odenton, MD (US)

Correspondence Address: Dresch IP Law, PLLC, P.O. Box 650903, Potomac Falls, VA, 20165, US

(21) Appl. No.: 12/534,850

(22) Filed: Aug. 3, 2009

Related U.S. Application Data
(60) Provisional application No. 61/138,522, filed on Dec. 17, 2008.

(51) Int. Cl. H05K 5/00

(52) U.S. Cl. 361/679.02

(57) ABSTRACT

A protective cover for an eReader includes first and second covers having interior and exterior surfaces, and pivotable with respect each other. A mounting device secures the eReader on the interior surface of the cover, and includes a first corner support engaging a first corner of the eReader, and a first elastic corner strap engaging a second corner of the eReader. A closure device includes a closure strap slot formed on the first cover, and a closure strap secured to at least the second cover. The closure strap wraps around the exterior surfaces of the first and second covers and engages the closure strap slot to secure the first and second covers in a closed position. A booklight pocket on the interior surface of the first or second covers, wherein the booklight pocket is configured to secure a portable booklight to the interior surface of the first or second cover.

### CROSS-REFERENCE TO RELATED APPLICATIONS

The present invention claims the benefit of U.S. Provisional Patent Application No. 61/138,522, filed Dec. 17, 2008, and entitled “PROTECTIVE COVER FOR AN eREADER”, the entire contents of which are incorporated herein by reference.

### FIELD OF THE INVENTION

The present invention is directed toward a jacket or cover, and more specifically, to a protective jacket or cover for an eReader.

### BACKGROUND OF THE INVENTION

Recently, eReaders such as electronic books have become increasingly popular. Such eReaders include a display, such as a liquid crystal display (LCD), for displaying the contents or text of an electronic book.

An eReader is designed to be lightweight, compact, and portable. In this manner, an eReader may be easily stowed, for example, in a book bag, purse, pocket, briefcase, etc. and transported by a user, or simply be hand-carried by the user. As a result of this portability, the eReader may be susceptible to wear or damage from other objects, liquids, etc., including for example, scratches, dings, chipping, etc.

To protect the eReader, and particularly the display of the eReader, from wear or damage, it is known to provide a protective cover for an eReader. Conventional covers commonly may have limited applications, may be cumbersome or difficult to use, may not reliably hold or secure the eReader therein, may not protect all surfaces of the eReader, and/or may inhibit access to input/output controls of the eReader.

### SUMMARY OF THE INVENTION

These problems and others are addressed by the present invention, a first exemplary embodiment of which comprises a protective cover for an eReader, including a first cover having an interior and an exterior surface, a second cover having an interior and an exterior surface, wherein the first cover and second cover are pivotable with respect each other, a mounting device for securing the eReader on the interior surface of one of the first cover and the second cover, and a closure device including a closure strap slot formed on the first cover, and a closure strap secured to at least the second cover, the closure strap wrapping around the exterior surface of the first cover and the exterior surface of the second cover, and configured to engage the closure strap slot to secure the first cover and the second cover in a closed position.

Another exemplary embodiment comprises a protective cover for an eReader including a first cover having an interior and an exterior surface, a second cover having an interior and an exterior surface, wherein the first cover and second cover are pivotable with respect each other, a mounting device for securing the eReader on the interior surface of one of the first cover and the second cover, and a closure device that secures the first cover and the second cover in a closed position, wherein the mounting device includes a first corner support configured to engage a first corner of the eReader, and a first elastic corner strap configured to engage a second corner of the eReader.

Another exemplary embodiment comprises a protective cover for an eReader, including a first cover having an interior and an exterior surface, a second cover having an interior and an exterior surface, wherein the first cover and second cover are pivotable with respect each other, a mounting device for securing the eReader on the interior surface of one of the first cover and the second cover, and a booklight pocket on the interior surface of one of the first cover and the second cover, wherein the booklight pocket is configured to secure a portable booklight to the interior surface of one of the first cover and the second cover.

Another exemplary embodiment comprises protective cover for an eReader, including a first cover having an interior and an exterior surface, a second cover having an interior and an exterior surface, wherein the first cover and second cover are pivotable with respect each other, a mounting device for securing the eReader on the interior surface of one of the first cover and the second cover, wherein the mounting device includes a first corner support configured to engage a first corner of the eReader, and a first elastic corner strap configured to engage a second corner of the eReader, a closure device including a closure strap slot formed on the first cover, and a closure strap secured to at least the second cover, the closure strap wrapping around the exterior surface of the first cover and the exterior surface of the second cover, and configured to engage the closure strap slot to secure the first cover and the second cover in a closed position, and a booklight pocket on the interior surface of one of the first cover and the second cover, wherein the booklight pocket is configured to secure a portable booklight to the interior surface of the one of the first cover and the second cover.

In this manner, the exemplary embodiments of the present invention provide a protective cover or jacket for an eReader that easily and reliably secures and protects a variety of types of eReaders, while also being lightweight, compact, and portable.

The exemplary embodiments can provide a protective jacket or cover having a closure strap that fully wraps around the cover and engages a closure strap slot to secure the cover in a closed position. The closure strap also can be configured to engage the closure strap slot to secure the cover in a full open position.

The exemplary embodiments also can provide a protective jacket or cover having a mounting system that securely and reliably holds the eReader device in the cover, and more particularly, a variety of types of eReaders by various manufacturers. In this manner, the mounting system can be universal for a plurality of eReader devices, and therefore, does not need to be configured specifically for one particular device, model, or manufacturer. The exemplary mounting system of the invention is easy to use, reliably and firmly holds or secures the eReader in place inside the protective cover, and can be used with eReaders of various sizes, shapes, and weights, and made by various manufacturers.

Additionally, the exemplary embodiments can provide a protective cover including a pocket for receiving a base of a portable and/or flexible booklight such that a booklight can be easily and effortlessly carried with the eReader, for example, at all times. The exemplary embodiments also can be configured to receive and seamlessly integrate and store the booklight within the protective cover, for example, in the spine of the protective cover when the eReader is not in use. In this manner, a lightweight, durable, and compact booklight can be easily collapsed and stored inside the protective cover along with the eReader, thereby providing a booklight that is easily and conveniently carried or transported along with the eReader, while also protecting the booklight from damage. Thus, a user of an eReader can easily and conveniently illuminate the screen of the eReader in instances in which the level of ambient light is limited or reduced.

The exemplary protective cover provides an important advantage in that the cover can provide full surface protection for the eReader device. In other exemplary embodiments, the protective cover can include padded cover portions that permit the user to comfortable grasp or hold the protective cover, while also increasing the amount of force that can be absorbed by the protective cover, thereby increasing a level of protection provided by the cover for the eReader contained therein, as well as for the optional booklight stored therein. The protective cover also can include a solid front panel and/or rear panel to protect the eReader and/or booklight.

In an exemplary embodiment, the protective cover can include one or more soft, plush, compressible, or padded interior surfaces to protect or cushion the eReader within the protective cover, as well as to protect or cushion the optional booklight.

An exemplary embodiment of the protective cover also may include one or more interior pockets for storage of notes, business cards, documents, memory cards, and other items. The protective cover also may include a device for conveniently holding or securing a pen, pencil, stylus, etc., for example, in the spine of the jacket or cover.

The exemplary embodiments of the protective cover can provide a user with full access and use of most or all of the input/output ports and controls, etc. of the eReader without having to remove the protective cover from the eReader.

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 illustrates a perspective view of a protective cover for an e-Reader according to an embodiment of the present invention.

FIG. 2 illustrates a plan view of a protective cover for an e-Reader according to an embodiment of the present invention.

FIG. 3 illustrates a bottom view of a protective cover for an e-Reader according to an embodiment of the present invention.

FIG. 4 illustrates a side plan view of a protective cover for an e-Reader according to an embodiment of the present invention.

FIG. 5 illustrates a detail A of FIG. 2.

FIG. 6 illustrates a detail C of FIG. 2.

FIG. 7 illustrates another perspective view of a protective cover for an e-Reader according to an embodiment of the present invention.

FIG. 8 illustrates another perspective view of a protective cover for an e-Reader according to an embodiment of the present invention.

FIG. 9 illustrates a perspective view of a protective cover for an e-Reader according to another embodiment of the present invention.

FIG. 10 illustrates a partial perspective view of the protective cover of FIG. 9.

### DETAILED DESCRIPTION OF THE EXEMPLARY EMBODIMENTS

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

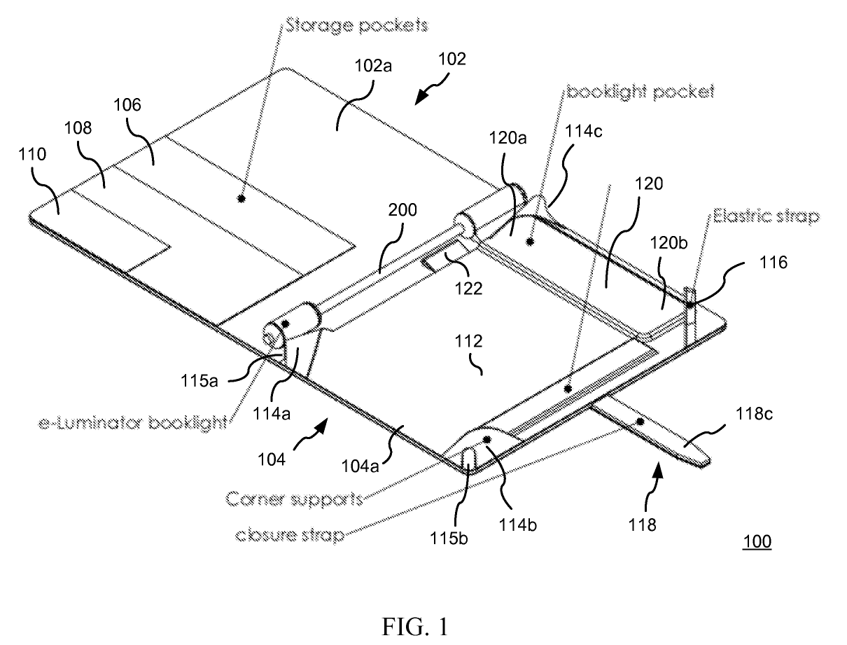

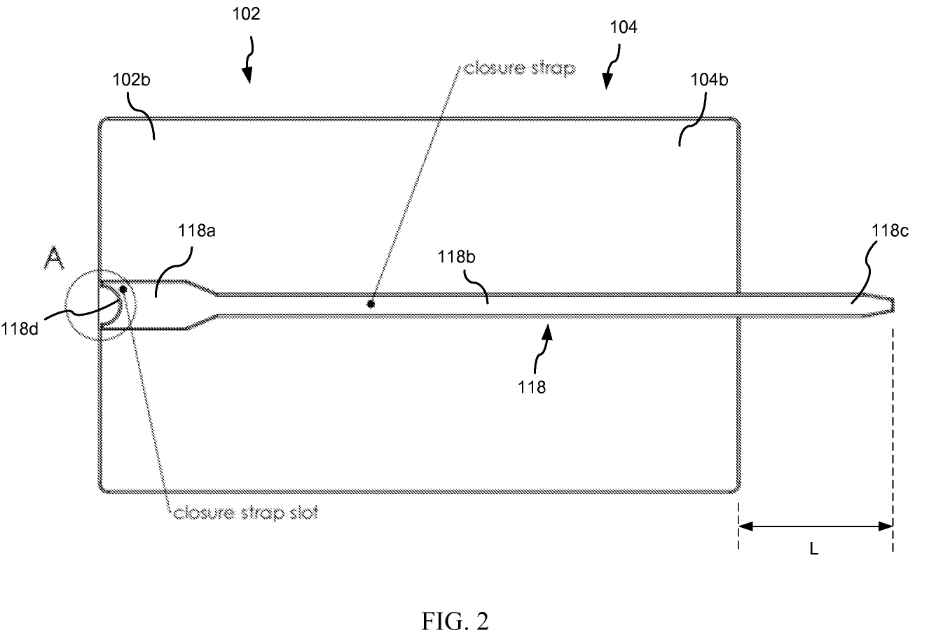

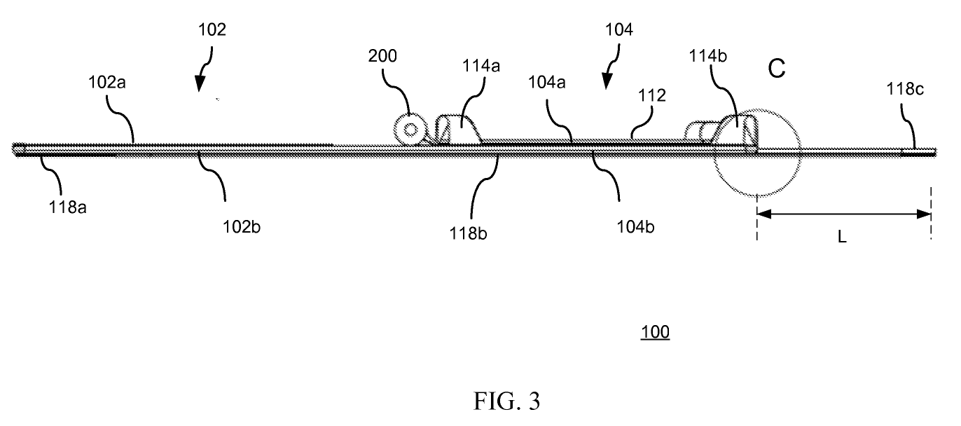

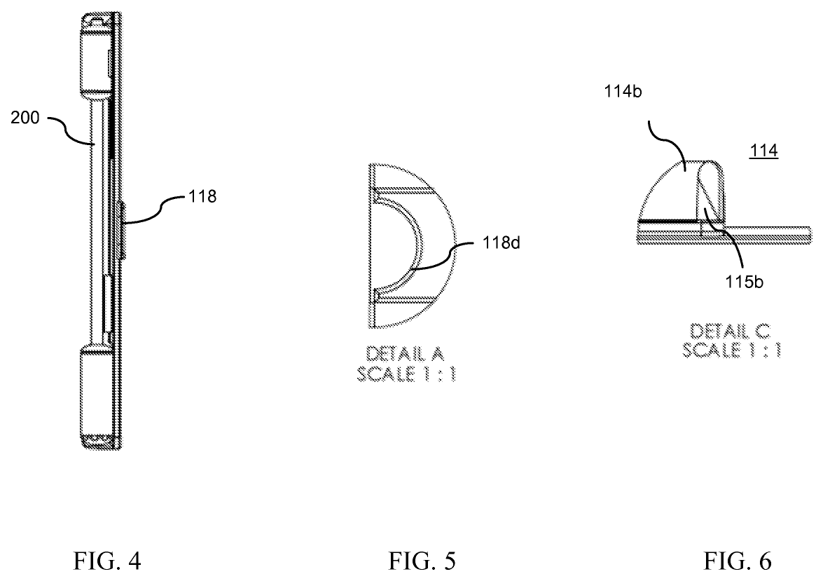

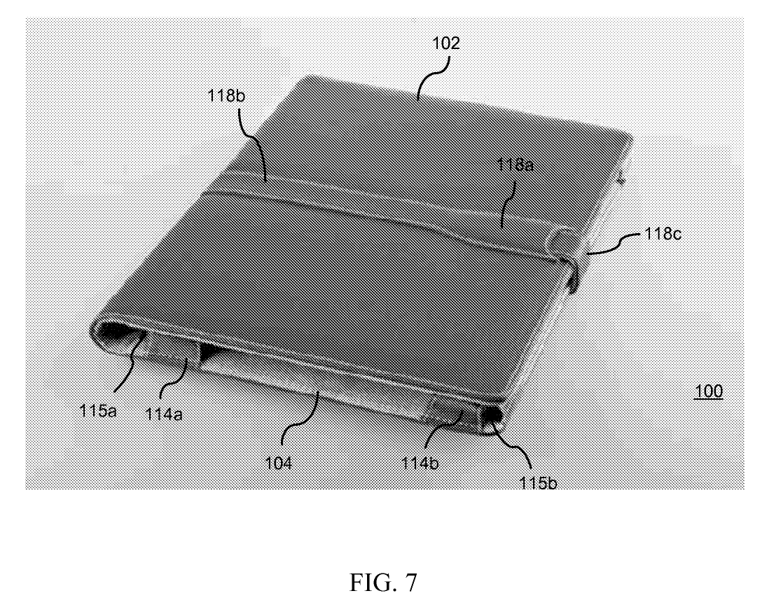

Referring now to the drawings, FIGS. 1-10 illustrate exemplary embodiments of a protective cover for an eReader.

As shown in FIG. 1, an exemplary embodiment of a protective cover 100 for an eReader includes a front cover 102 and a rear cover 104. The front cover 102 and rear cover 104 each have interior 102a, 104a and exterior surfaces 102b, 104b. The front cover 102 and rear cover 104 are pivotable with respect to one another about a spine such that the covers are movable between a closed position, a flat open position, and a full open position, as well as positions therebetween. The spine can be an integral portion of the cover that folds when the front cover 102 is overlapped with the rear cover 104. Alternatively, the spine can be a separate section (e.g., a reinforced section) that joins the front and rear covers 102 and 104.

For purposes of this disclosure, the closed position is defined as a position in which the front cover 102 overlaps the rear cover 104 and the interior surface 102a of the front cover 102 is opposed to the interior surface 104a of the rear cover 104. The flat open position is defined as a position in which the front cover 102 and the rear cover 104 are disposed in substantially the same plane and do not overlap each other. The full open position is defined as a position in which the front cover 102 overlaps the rear cover 104 and the exterior surface 102b of the front cover 102 is opposed to the exterior surface 104b of the rear cover 104.

In the closed position, the front cover 102 and rear cover 104 are configured to cover the entire surface of the eReader device stored therein, thereby providing protection for all surfaces of the eReader.

Closure Strap

Exemplary embodiments of a protective cover having a closure strap will now be described.

As shown in FIGS. 1-4 and 7, an exemplary protective cover 100 includes a closure strap 118 that fully wraps around the exterior surface of the cover 100. The closure strap includes a fixed end 118a that is adjacent to a free edge of the exterior surface of the front cover 102. The closure strap further includes a fixed central portion 118b extending across the front cover 102 and the rear cover 104, and a free end 118c extending from a free edge of the exterior surface of the rear cover 104.

In alternative embodiment, the fixed end can be formed adjacent to the free edge of the rear cover 104, and the free end 11 c can extend from the free edge of the front cover 102.

In an exemplary embodiment, the fixed end 118a can include a closure strap slot 118d that is configured to receive the free end 118a of the closure strap 118. A width of the fixed end 118a and a width of the closure strap slot 118d are selected to be equal to or greater than the free end 118c. The closure strap 118 can be coupled to the exterior surfaces of the front cover 102 and the rear cover 104, for example, by sewing or stitching, using an adhesive, or the like.

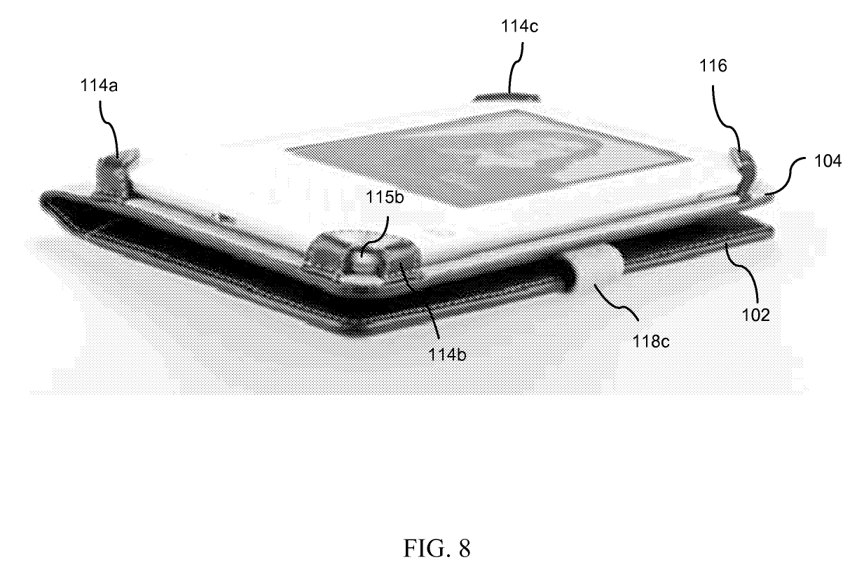

In operation, when the front cover 102 and rear cover 104 are in the closed position, the free end 118c of the closure strap 118 has a length L that is sufficient to engage the closure strap slot 118d to secure the cover 100 in the closed position, as shown in FIG. 7. Additionally, the length L of the free end 118c of the closure strap 118 can be sufficient to engage the closure strap slot 118d to secure the cover 100 in the full open position, as shown in FIG. 8.

As shown in the Detail A of FIG. 5, the closure strap slot 118d can include a semi-circular opening formed in the open edge of the closure strap slot 118d, thereby improving the insertion of the free end 118c into the closure strap slot 118d.

Mounting System

Exemplary embodiments of a protective cover 100 having an eReader mounting system that securely and reliably holds the eReader device in the cover will now be described.

As shown in FIG. 1, an exemplary mounting system can include a four-point mounting system to hold or secure the eReader in place against the interior surface of the rear cover 104 of the protective cover. The mounting system can include, for example, a pocket at one or more of the four corners of the protective cover. Each of the pockets is configured to engage a corresponding corner of the eReader. In the mounting system, at least one of the four corners includes an elastic strap for engaging a corresponding corner of the eReader.

For example, as illustrated in FIGS. 1 and 3-8, an exemplary embodiment of a mounting system can include a pocket 114a, 114b, 114c, respectively, provided at each of the first, second, and third corners of the protective cover (e.g., the upper left corner, the lower left corner, and the lower right corner of the protective cover 100, as shown in FIG. 1). The mounting system can include an elastic strap 116 at the fourth corner of the protective cover (e.g., the upper right corner, as shown in FIG. 1).

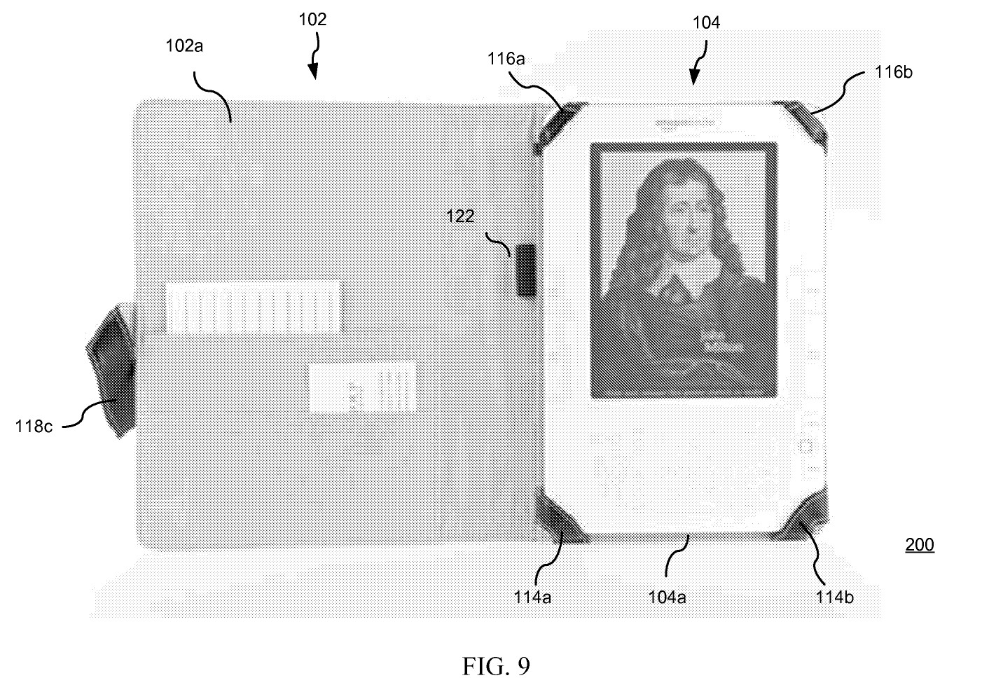

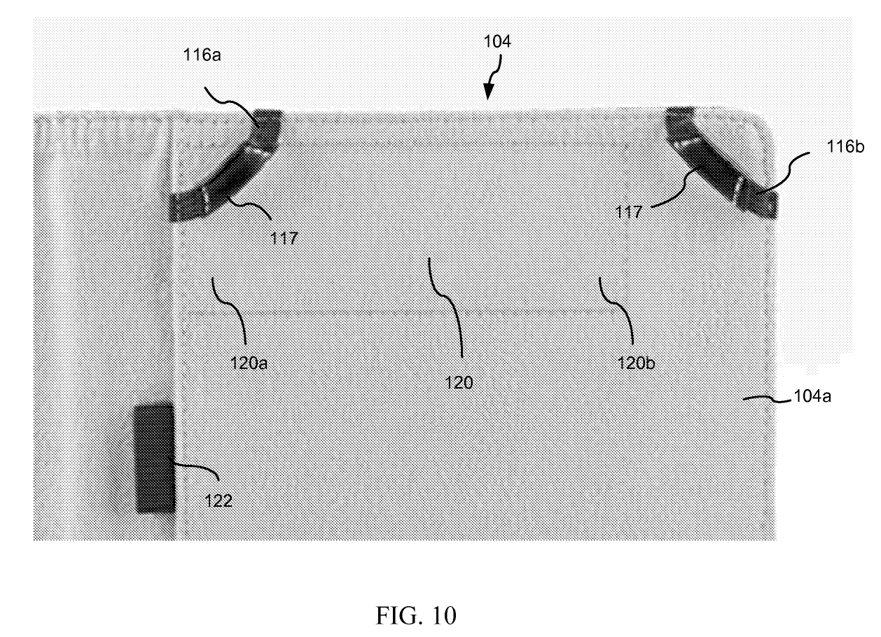

With reference to FIGS. 9 and 10, another exemplary embodiment of a mounting system for a protective cover 200 for an eReader will now be described.

The exemplary mounting system can include a pocket 114a, 114b provided at each of the first and second corners of the protective cover 200 (e.g., the lower left corner and the lower right corner of the protective cover 200, as shown in FIG. 9). The mounting system can include elastic straps 116a and 116b at the third and fourth corners of the protective cover 200 (e.g., the upper left corner and the upper right corner, as shown in FIGS. 9 and 10).

In this manner, the exemplary embodiments shown for example in FIGS. 1 and 9 can provide a protective jacket or cover having a mounting system that securely and reliably holds the eReader device in the cover. Additionally, the mounting system can be universal for a plurality of eReader devices, and therefore, does not need to specifically be configured for one particular device, model, or manufacturer. The exemplary mounting system of the invention is easy to use, while also being capable of reliably and firmly holding or securing the eReader device in place in the protective cover, and can be used with eReaders of various sizes, shapes, and weights, and made by various manufacturers.

With reference to FIGS. 1, 6, 8, and 9, exemplary features of the corner supports will now be described.

The corner supports 114a, 114b, 114c can include a flexible body extending diagonally from a first side of a corner of the protective cover to a second side of a corner of the protective cover. The flexible body can include an opening 115a, 115b, which may reduce or eliminate creasing of the flexible body while also providing a seat for engaging a corner of the eReader in a mounted state.

The corner supports 114a, 114b, 114c can be formed from a material, for example, that provides at least some traction on the corner of eReader to reduce or prevent slippage of the eReader from the corner supports, such as leather, suede leather, rubber, felt, etc. For example, in an exemplary embodiment, the corner supports can be formed from leather, or include leather cover portions, for reducing or preventing slippage of the eReader from the corner supports. The leather corner supports or cover portions for the corner supports also provide an advantage in that they may be aesthetically pleasing to the user.

With reference to FIGS. 1, 9, and 10, exemplary features of the elastic straps 116, 116a, 116b will now be described.

The elastic straps 116, 116a, 116b can extend diagonally from a first side of a corner of the protective cover to a second side of a corner of the protective cover. In operation, one or more corners of an eReader can be inserted into one or more corner supports 114 of the protective cover 100, 200. Next, one or more elastic straps 116, 116a, and/or 116b can be stretched over one or more corners of the eReader.

In this manner, the exemplary mounting system can easily, securely, and reliably hold the eReader device in the cover. Additionally, since the elastic straps 116 can be stretched over the corners of the eReader, the mounting system can be universal for a plurality of eReader devices, and therefore, does not need to be configured specifically for one particular device, model, or manufacturer. Hence, the exemplary mounting system of the invention is easy to use, reliably and firmly holds or secures the eReader device in place in the protective cover, and can be used with eReaders of various sizes, shapes, and weights, and made by various manufacturers.

The elastic straps 116, 116a, and/or 116b can be formed from a suitable elastic material. As illustrated in FIG. 10, the elastic straps also can include a cover portion or gripping feature 117 that provides at least some traction on the corner of eReader to reduce or prevent slippage of the eReader from the corner supports. For example, the cover portion or gripping feature 117 can be leather, suede leather, rubber, felt, etc. In an exemplary embodiment, the elastic straps can include leather cover portions 117 for reducing or preventing slippage of the eReader from the corner supports, as illustrated in FIG. 10. The leather cover portions 117 also provide an advantage in that they may be aesthetically pleasing to the user.

In this manner, the exemplary embodiments provide a mounting system that securely and reliably holds the eReader device in the cover. Additionally, the mounting system can be universal for a plurality of eReader devices, and therefore, does not need to be configured specifically for one particular device, model, or manufacturer. The exemplary mounting system of the invention is easy to use, reliably and firmly holds or secures the eReader device in place in the protective cover, and can be used with eReaders of various sizes, shapes, and weights, and made by various manufacturers.

The exemplary embodiments of the protective cover can provide a user with full access and use of most or all of the input/output ports and controls, etc. of the eReader without having to remove the protective cover from the eReader.

Booklight Pocket

With reference to FIGS. 1, 3, and 4, exemplary embodiments of a protective cover having a booklight pocket will now be described.

As shown in FIG. 1, the protective cover 100 can include a pocket 120 for receiving a base of a portable and/or flexible book light 200 such that the booklight can be easily and effortlessly carried with the eReader, for example, at all times. The pocket 120 can be formed, for example, at an upper end of the interior surface of the rear cover 104 such that the book light 200 can be positioned to extend from the upper end of the spine toward the lower end of the spine of the cover. In other embodiments, the pocket 120 can be formed at other locations on the interior of the rear cover 104, or at locations on the interior of the front cover 102. The pocket 120 can be formed on the same cover as the mounting system or on a different cover than the cover having the mounting system.

The pocket 120 can be integrally formed or sewn into the interior surface of the cover or coupled to the interior surface of the cover, for example, by another adhering means, such as using a glue, adhesive tape, etc.

The pocket 120 includes an open end 120a adjacent to the spine of the protective cover 100 for receiving the base of a booklight 200. The pocket 120 can include a closed end 120b at an opposite end from the open end 120a. In other embodiments, both ends of the pocket can be open ends. A shape of the pocket 120 can be configured to correspond to a shape of the base of the booklight 200.

As shown in FIG. 1, in operation, the base of the flexible book light 200 is inserted into the pocket 120 until the booklight is positioned along the spine of the protective cover 100. In this manner, the protective cover 100 can seamlessly integrate and store the booklight 200 within the protective cover 100 in the spine of the cover when the cover 100 is in the closed position. When the cover is in the flat open position or the full open position, the user can pivot the flexible book light 200 about the base, thereby moving the booklight 200 from a stored position in which the booklight 200 is aligned with the spine of the cover 100 and into an open position in which at least a portion of the booklight 200 extends away from the cover 100. A position of the booklight 200 can then be manipulated to focus the light on the display of the eReader. In this way, the present invention provides a protective cover 100 including an integral booklight that is compact and portable.

Other exemplary embodiments of the protective cover will now be described with reference again to FIGS. 1-10.

In an exemplary embodiment, the front cover 102 and/or the rear cover 104 can include a solid front panel and/or rear panel. In another embodiment, the front cover 102 and/or the rear cover 104 can include a padded exterior cover. The exterior of the front and rear covers 102 and 104 can be covered with leather.

In another exemplary embodiment, one or more of the front cover 102 and the rear cover 104 can include a soft, plush, compressible, or padded interior surface to cushion the eReader within the protective cover. For example, the interior surface can be formed from a soft, microfiber material.

The interior surface of the front cover 102 can include one or more pockets or slots 106, 108, 110 for storing notes, business cards, documents, and/or other items, such as memory cards (e.g., MMC/SD Card Slots). The protective cover 100 also may include a device, such as an integral elastic loop 122, for holding or securing a pen, pencil, stylus, etc., for example, in the spine of the jacket or cover.

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

Like numbers refer to like elements throughout. In the figures, the thickness of certain lines, layers, components, elements or features may be exaggerated for clarity.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

What is claimed is:

1. A protective cover for an eReader, comprising:
a first cover having an interior and an exterior surface;
a second cover having an interior and an exterior surface, wherein the first cover and second cover are pivotable with respect each other;
a mounting device for securing the eReader on the interior surface of one of the first cover and the second cover; and
a closure device including:
a closure strap slot formed on the first cover; and
a closure strap secured to at least the second cover, the closure strap wrapping around the exterior surface of the first cover and the exterior surface of the second cover, and configured to engage the closure strap slot to secure the first cover and the second cover in a closed position.

2. The protective cover of claim 1, wherein the closure strap includes:
a fixed end that is adjacent to a free edge of the first cover;
a free end extending a predetermined distance from a free edge of the second cover; and
a fixed central portion extending over the first cover and the second cover and coupling the fixed end to the free end.

3. The protective cover of claim 2, wherein the free end of the closure strap is configured to engage the closure strap slot to secure the first cover and the second cover in the closed position.

4. The protective cover of claim 2, wherein the closure strap slot is integrally formed by the fixed end of the closure strap.

5. The protective cover of claim 4, wherein a width of each of the closure strap slot and the fixed end of the closure strap is one of equal to and greater than a width of the free end of the closure strap.

6. The protective cover of claim 5, wherein the closure strap slot includes a semicircular opening for receiving the fixed end of the closure strap.

7. The protective cover of claim 1, wherein the first cover and the second cover are pivotable with respect each other between at least the closed position, a flat open position, and a full open position,
wherein the closed position is a position in which the first cover overlaps the second cover and the interior surface of the first cover is opposed to the interior surface of the second cover,
wherein the flat open position is a position in which the first cover and the second cover are disposed in substantially the same plane and do not overlap each other, and
wherein the full open position is a position in which the first cover overlaps the second cover and the exterior surface of the first cover is opposed to the exterior surface of the second cover.

8. The protective cover of claim 7, wherein the free end of the closure strap is configured to engage the closure strap slot to secure the first cover and the second cover in the full open position.

9. The protective cover of claim 1, wherein the mounting device includes at least one of a corner support and an elastic corner strap that secures the eReader on the interior surface of the first cover or the second cover.

10. A protective cover for an eReader, comprising:
a first cover having an interior and an exterior surface;
a second cover having an interior and an exterior surface, wherein the first cover and second cover are pivotable with respect each other;
a mounting device for securing the eReader on the interior surface of one of the first cover and the second cover; and
a closure device that secures the first cover and the second cover in a closed position,
wherein the mounting device includes:
a first corner support configured to engage a first corner of the eReader; and
a first elastic corner strap configured to engage a second corner of the eReader.

11. The protective cover of claim 10, wherein the mounting device includes a four point mounting device that engages each of four corners of the eReader.

12. The protective cover of claim 10, wherein the mounting device includes a second corner support configured to engage a third corner of the eReader.

13. The protective cover of claim 12, wherein the mounting device includes a third corner support configured to engage a fourth corner of the eReader.

14. The protective cover of claim 12, wherein the mounting device includes a second elastic corner strap configured to engage a fourth corner of the eReader.

15. The protective cover of claim 10, wherein the mounting device includes a second elastic corner strap configured to engage a third corner of the eReader.

16. The protective cover of claim 10, wherein the first corner support includes a flexible body extending diagonally from a first side of a first corner of the protective cover to a second side of the first corner of the protective cover.

17. The protective cover of claim 16, wherein the first corner support includes an opening adjacent to the first corner of the protective cover and forming a seat configured to engage the first corner of the eReader in a secured state.

18. The protective cover of claim 10, wherein the first corner support includes a gripping surface that frictionally engages a surface of the eReader.

19. The protective cover of claim 10, wherein the first elastic corner strap extends diagonally from a first side of a second corner of the protective cover to a second side of the second corner of the protective cover.

20. The protective cover of claim 10, wherein the first elastic corner strap includes a gripping surface that frictionally engages a surface of the eReader.

21. A protective cover for an eReader, comprising:
a first cover having an interior and an exterior surface;
a second cover having an interior and an exterior surface, wherein the first cover and second cover are pivotable with respect each other;
a mounting device for securing the eReader on the interior surface of one of the first cover and the second cover; and
a booklight pocket on the interior surface of one of the first cover and the second cover,
wherein the booklight pocket is configured to secure a portable booklight to the interior surface of one of the first cover and the second cover.

22. The protective cover of claim 21, wherein each of the mounting device and the booklight pocket are on the first cover.

23. The protective cover of claim 21, wherein the mounting device is on the first cover and the booklight pocket is on the second cover.

24. The protective cover of claim 21, wherein the mounting device secures the eReader over the booklight pocket when the eReader is secured to the interior surface of the one of the first cover and the second cover.

25. The protective cover of claim 21, wherein the booklight pocket is located adjacent to an upper end of the interior surface of the one of the first cover and the second cover.

26. The protective cover of claim 21, wherein one of a size and a shape of the booklight pocket corresponds to a corresponding one of a size and a shape of a base of the portable booklight.

27. The protective cover of claim 21, wherein the booklight pocket includes an open end adjacent to a spine of the protective cover formed between the first cover and the second cover for receiving a base of the portable booklight therein.

28. The protective cover of claim 27, wherein the booklight pocket includes a closed end at an opposite end from the open end.

29. A protective cover for an eReader, comprising:
a first cover having an interior and an exterior surface;
a second cover having an interior and an exterior surface, wherein the first cover and second cover are pivotable with respect each other;
a mounting device for securing the eReader on the interior surface of one of the first cover and the second cover,
wherein the mounting device includes:
a first corner support configured to engage a first corner of the eReader; and
a first elastic corner strap configured to engage a second corner of the eReader;
a closure device including:
a closure strap slot formed on the first cover; and
a closure strap secured to at least the second cover, the closure strap wrapping around the exterior surface of the first cover and the exterior surface of the second cover, and configured to engage the closure strap slot to secure the first cover and the second cover in a closed position; and
a booklight pocket on the interior surface of one of the first cover and the second cover,
wherein the booklight pocket is configured to secure a portable booklight to the interior surface of the one of the first cover and the second cover.
